(19) United States
(12) Patent Application Publication
(10) Pub. No.: US 2015/0311104 A1
(43) Pub. Date: Oct. 29, 2015

(54) METHOD AND SYSTEM FOR ALIGNING AND ORIENTING DIES

(71) Applicant: Avago Technologies General IP (Singapore) Pte. Ltd., Singapore (SG)

(72) Inventor: Hui Xu, Santa Clara, CA (US)

(73) Assignee: Avago Technologies General IP (Singapore) Pte. Ltd., Singapore (SG)

(21) Appl. No.: 14/260,858

(22) Filed: Apr. 24, 2014

(51) Int. Cl. H01L 21/68; H01L 23/544; H01L 21/78; H01L 21/66; H01L 21/67; H01L 23/00

(52) U.S. Cl. CPC H01L 21/681; H01L 21/67144; H01L 24/97; H01L 21/78; H01L 22/12; H01L 23/544

(57) ABSTRACT

A precision die-attach system and method are provided for precisely aligning and orienting multiple dies relative to one another and relative to a mounting surface and for attaching the dies to the mounting surface while maintaining the relative alignment and orientation. The system includes an alignment tool that is a precisely manufactured part having receptacles formed therein that are precisely aligned with one another. The receptacles hold the respective dies in positions and with orientations that are precisely aligned and oriented with the respective receptacles. Because the receptacles are precisely aligned and oriented relative to one another, the respective dies held therein are precisely aligned and oriented relative to one another. The die-attach system includes a mechanism for maintaining the precise alignment and orientation of the dies within the respective receptacles as the system places the dies on the mounting surface.

### TECHNICAL FIELD OF THE INVENTION

The invention relates to die-attach processes and systems, and more particularly, to a precision die-attach method and system for precisely aligning and orienting dies on a mounting surface.

### BACKGROUND OF THE INVENTION

In optical communications networks, optical communications modules are used to transmit and/or receive optical signals over optical fibers. An optical communications module may be an optical transceiver module having transmit and receive capabilities, an optical transmitter module having only transmit capabilities or an optical receiver module having only receive capabilities. An optical transceiver or transmitter module includes at least one light source, which is typically a laser diode or light-emitting diode (LED), that converts electrical data signals into optical data signals that are transmitted over an optical fiber coupled to the transceiver or transmitter module. Various types of semiconductor lasers are typically used for this purpose, including, for example, vertical cavity surface emitting lasers (VCSELs) and edge emitting lasers, which may be further divided into subtypes that include Fabry Perot (FP) and Distributed Feedback (DFB) lasers. An optical transceiver or receiver module includes at least one light detector, which is typically a photodiode, that receives optical data signals transmitted over an optical fiber and converts them into electrical data signals.

Some optical transmitter or transceiver modules have a single transmit channel comprising a single laser, which is sometimes referred to as a singlet. Other optical transmitter or transceiver modules have multiple transmit channels comprising multiple lasers. The multi-channel optical transmitter or transceiver module is commonly referred to as a parallel optical transmitter or transceiver module. Similarly, some optical receiver or transceiver modules have a single receive channel comprising a single photodiode, which is sometimes referred to as a singlet. Other optical receivers or transceiver modules have multiple receive channels comprising multiple photodiodes. The multi-channel optical receiver or transceiver module is commonly referred to as a parallel optical receiver or transceiver module.

There is an ever-increasing demand for optical transmitter, receiver and transceiver modules that have increasingly larger numbers of transmit and/or receive channels. Of course, increasing the number of channels allows the bandwidth capacity of an optical communications network to be increased. In order to meet this demand, it is known to fabricate many lasers on a single semiconductor wafer and then to dice the wafer into chips where each chip contains an array of lasers. For example, it is known to fabricate one-dimensional or two-dimensional arrays of laser diodes and photodiodes in this manner. Fabricating arrays of laser diodes and photodiodes in this manner allows the spacing, or pitch, between adjacent laser diodes or photodiodes of the arrays to be precisely controlled. Precisely controlling the pitch is important because in many cases the ends of optical fibers held in a connector that mates with the optical communications module are spaced apart by a very precise pitch. The pitch between adjacent fiber ends needs to be exactly matched by the pitch between adjacent laser diodes or photodiodes of the arrays in order to prevent optical losses and performance problems. For example, in some conventional arrangements, the pitch is 250 micrometers (microns).

It is also very important to secure the arrays of laser diodes or photodiodes on the electrical subassembly (ESA) at very precise locations and with very precise orientations. The arrays must be located on the ESA at precise locations and with precise orientations so that the respective optoelectronic elements (i.e., laser diodes or photodiodes) of the arrays are precisely aligned with an optics system of the optical communications module and/or with ends of optical fibers held in a connector that mates with the optical communications module. In addition, in optical transceiver modules that include both an array of laser diodes and an array of photodiodes, it is often necessary to ensure that the laser diodes of the laser diode array are aligned with the photodiodes of the photodiode array because the connector typically holds the ends of the transmit and receive optical fibers for carrying the optical signals produced by the laser diodes and received by the photodiodes, respectively.

Typical precision die attach processes use a pick-and-place machine that includes a machine vision system to compare the location of the array die with the location of one or more fiducial marks as the die is being picked up from one location and placed on the ESA. Precisely locating and orienting the array die relative to the fiducial mark ensures that the array die is precisely located and oriented on the ESA. The fiducial mark may be on the substrate of the ESA or it may be at some other location, such as on a die that was previously attached to the substrate of the ESA.

When having to align multiple array dies with one another on the ESA, the accuracy with which the dies are attached needs to be even more precise. In addition, when dealing with array dies as opposed to singlets, the requirement of precisely controlling the rotation of the array die places more stringent demands on the pick-and-place machine and machine vision system. Pick-and-place machines with vision systems that are capable of meeting these demands typically cost millions of dollars, which increases the overall costs of producing the optical communications module.

Accordingly, a need exists for a precision die-attach method and system that enable very precise die attachment to be achieved at relatively low costs.

### SUMMARY OF THE INVENTION

The present invention is directed to a precision die-attach system for aligning and orienting dies to be mounted on a mounting surface. In accordance with an embodiment, the system comprises first and second precision-alignment receptacles. The first receptacle has a bottom and at least first and second precision-formed side walls. The first and second precision-formed side walls that form a first orientation/alignment feature in the first receptacle having a precise shape and size for mating with first and second side walls of a first (integrated circuit) IC die. The second precision-alignment receptacle has a bottom and at least third and fourth precision-formed side walls. The third and fourth precision-formed side walls that form a second alignment/orientation feature in the second receptacle. The second alignment/orientation feature has a precise shape and size for mating with first and second side walls of a second IC die. Mating of the first and second IC dies with the first and second alignment/orientation features of the first and second receptacles, respectively, precisely aligns and orients the first and second IC dies with the first and second receptacles, respectively, and with one another. The precision die-attach system is configured to place the first and second IC dies onto a mounting surface while maintaining the precise alignment and orientation of the first and second IC dies with one another.

In accordance with another embodiment, the precision die-attach system comprises a precision-etched interposer. The precision-etched interposer comprises an etched first precision-alignment receptacle and an etched second precision-alignment receptacle, where the first and second receptacles are integrally formed in an etched material. The first precision-alignment receptacle has a bottom and at least first and second precision-etched side walls that form a first alignment/orientation feature in the first receptacle. The first corner having a precise shape and size for mating with first and second side walls of a first IC die. The etched second precision-alignment receptacle has a bottom and at least third and fourth precision-etched side walls. The third and fourth precision-etched side walls that form a second alignment/orientation feature in the second receptacle. The second alignment/orientation feature has a precise shape and size for mating with first and second side walls of a second IC die. Mating of the first and second IC dies with the first and second alignment/orientation features of the first and second receptacles, respectively, precisely aligns and orients the first and second IC dies with the first and second receptacles, respectively, and with one another. The precision die-attach system is configured to place the interposer having the first and second IC dies aligned and oriented with the first and second receptacles, respectively, onto a mounting surface while maintaining the precise alignment and orientation of the first and second IC dies with the first and second receptacles, respectively.

In accordance with an embodiment, the method comprises: providing first and second precision-alignment receptacles having precision-formed side walls that form first and second alignment/orientation features in the first and second receptacles, respectively; aligning and orienting the first and second IC dies with the first and second alignment/orientation features of the first and second receptacles, respectively; and placing the first and second IC dies onto a mounting surface while maintaining the precise alignment and orientation of the first and second IC dies with one another.

In accordance with another embodiment, the method comprises: providing a precision-etched interposer having first and second precision-alignment receptacles formed therein that have precision-etched side walls that form first and second alignment/orientation features in the first and second receptacles, respectively, having precise shapes and sizes for mating with first and second side walls of the first and second IC dies, respectively; aligning and orienting the first and second IC dies with the first and second alignment/orientation features of the first and second receptacles, respectively, and fixedly securing the first and second IC dies in the respective aligned and oriented positions; and aligning and orienting the interposer with a mounting surface and placing the interposer on the mounting surface while maintaining the alignment and orientation of the interposer with the mounting surface.

These and other features and advantages of the invention will become apparent from the following description, drawings and claims.

### BRIEF DESCRIPTION OF THE DRAWINGS

FIG. 1A illustrates a top plan view of first and second precision-alignment receptacles of the precision die-attach system prior to array dies being placed therein.

FIG. 1B illustrates a top plan view of the first and second precision-alignment receptacles shown in FIG. 1A after first and second array dies have been placed therein, respectively, but prior to the array dies being aligned and oriented in the receptacles.

FIG. 1C illustrates a top plan view of the first and second precision-alignment receptacles shown in FIG. 1B with the first and second array dies aligned and oriented in the first and second receptacles, respectively.

FIG. 1D illustrates a top plan view of the first and second precision-alignment receptacles shown in FIG. 1C with the first and second array dies aligned and oriented in the first and second receptacles, respectively, and with the receptacles being positioned over a mounting surface as the array dies are mounted on the mounting surface.

FIG. 1E illustrates a top plan view of the first and second array dies mounted on the mounting surface in alignment with a fiducial mark disposed on the mounting surface.

FIG. 1F illustrates a top plan view of a mounting surface on which the two dies shown in FIGS. 1B-1E have been mounted using the precision die-attach system shown in FIGS. 1A-1E.

FIG. 2 illustrates a top plan view of the receptacles in accordance with another illustrative embodiment in which 1×4 array dies are aligned and oriented by the respective side walls of the receptacles.

FIGS. 3A-3C illustrate top plan views of a precision-alignment receptacle in accordance with another illustrative embodiment for aligning and orienting dies and for maintaining the alignment and orientation of the dies as they are placed on the mounting surface.

FIG. 4 illustrates a top plan view of an etched interposer mounted on a mounting surface having receptacles formed thereon on which dies are aligned and oriented.

FIG. 5 illustrates a pictorial diagram of a plasma etching chamber that may be used to perform plasma etching to dice compound semiconductor wafers into dies.

FIG. 6 is a flowchart that represents the method performed by the system shown in FIG. 5.

FIGS. 7A-7E are side plan views of a compound semiconductor wafer as it is processed in accordance with the method represented by the flowchart shown in FIG. 6.

FIGS. 8-13 illustrate top plan views of compound semiconductor dies having a variety of non-rectangular shapes that have been made using the plasma etching method and system described above with reference to FIGS. 5-7E.

### DETAILED DESCRIPTION OF ILLUSTRATIVE EMBODIMENTS

The invention is directed to a precision die-attach system and method for precisely aligning and orienting multiple dies relative to one another and relative to a mounting surface and for attaching the dies to the mounting surface while maintaining the relative alignment and orientation. The die-attach system includes an alignment tool that is a precisely manufactured part having multiple precision-alignment receptacles formed therein that are precisely aligned with one another. Each of the precision-alignment receptacles is configured, or adapted, to receive a die and to hold the received die in a position and with an orientation that is precisely aligned and oriented with the precision-alignment receptacle. Because the precision-alignment receptacles are precisely aligned and oriented relative to one another, the respective dies held therein are precisely aligned and oriented relative to one another. The die-attach system includes a mechanism for maintaining the precise alignment and orientation of the dies within the respective receptacles as the system places the dies on the mounting surface, thereby maintaining the precise alignment and orientation of the dies throughout the die-attach process.

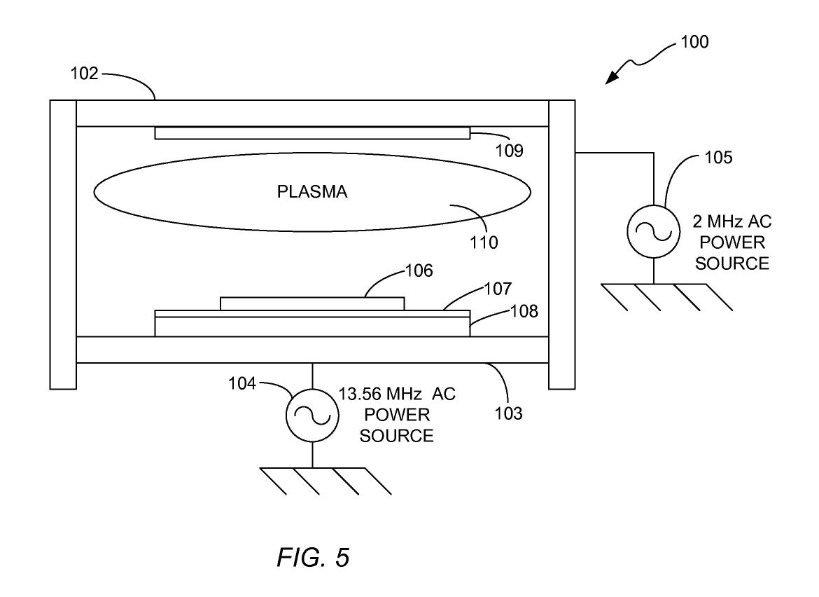

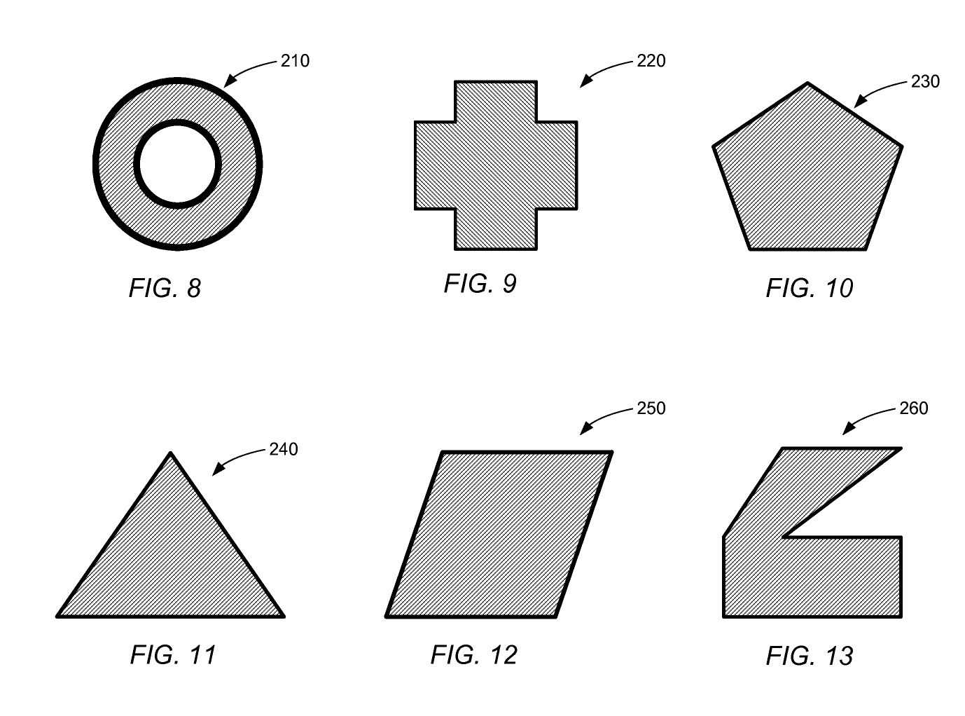

The precision die-attach system and method of the invention take advantage of new technology that allows dies to be singulated, or diced, with very high precision to produce dies that have very smooth side walls. This new technology is disclosed in U.S. application Ser. No. 13/758,265, entitled “METHODS FOR DICING A COMPOUND SEMICONDUCTOR WAFER, AND DICED WAFERS AND DIE OBTAINED THEREBY,” filed on Feb. 4, 2013, which is assigned to the assignee of the present application. As disclosed in that application, the dies obtained using the technology described therein have side walls that are so precise and smooth that the side walls of dies can be used as passive alignment features. Such dies can be used with the precision-alignment receptacles of the present invention because alignment and orientation of the dies within the respective receptacles ensure that the dies are precisely aligned and oriented with the receptacles and with one another. Because application Ser. No. 13/758,265 has not yet been published, portions of that application are disclosed herein and described below with reference to FIGS. 5-13.

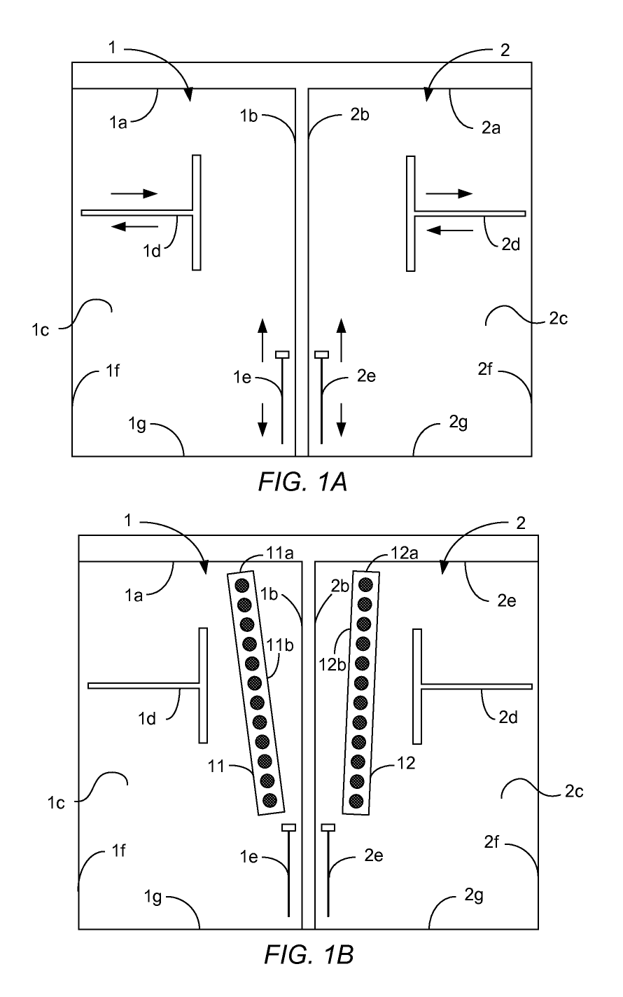

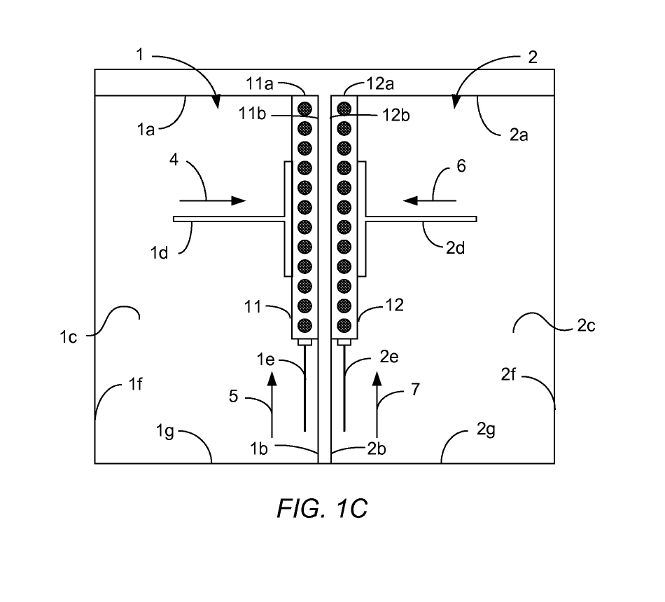

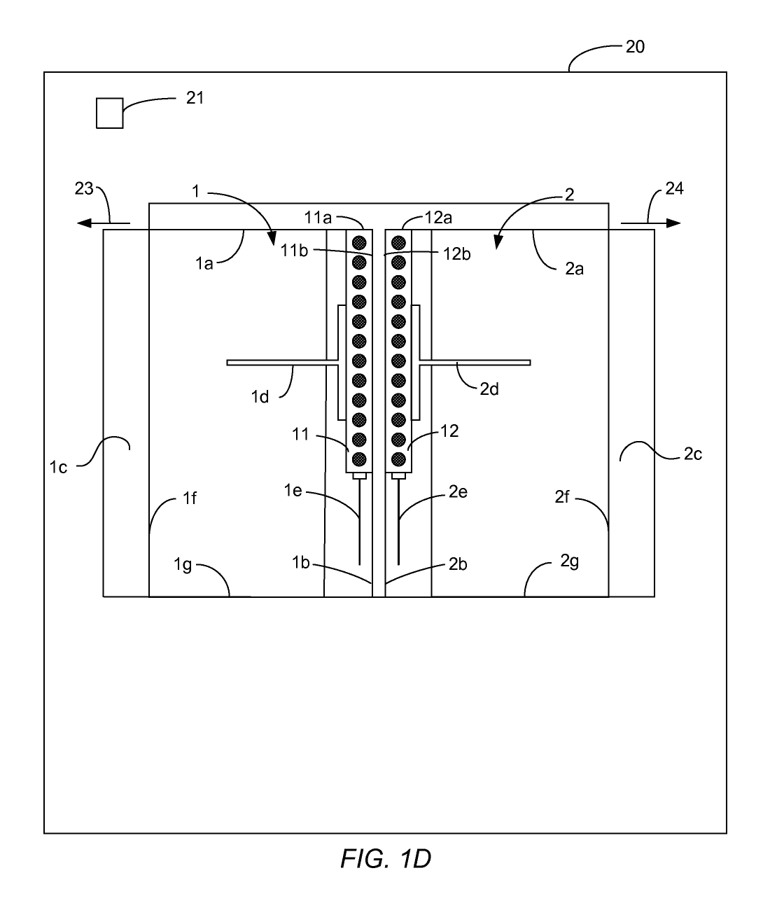

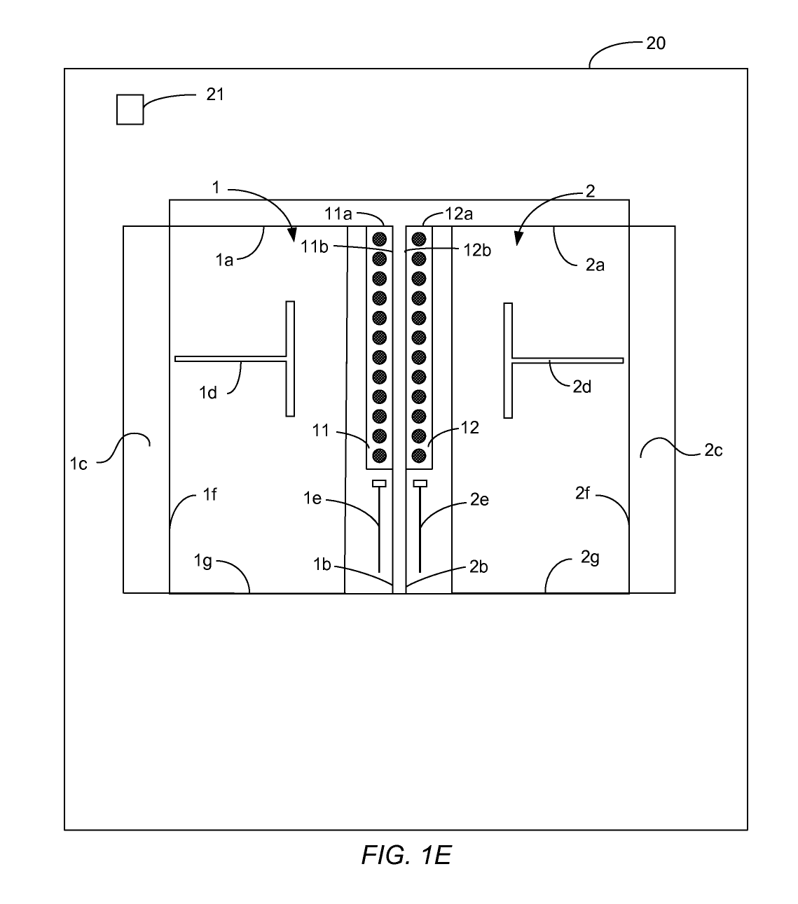

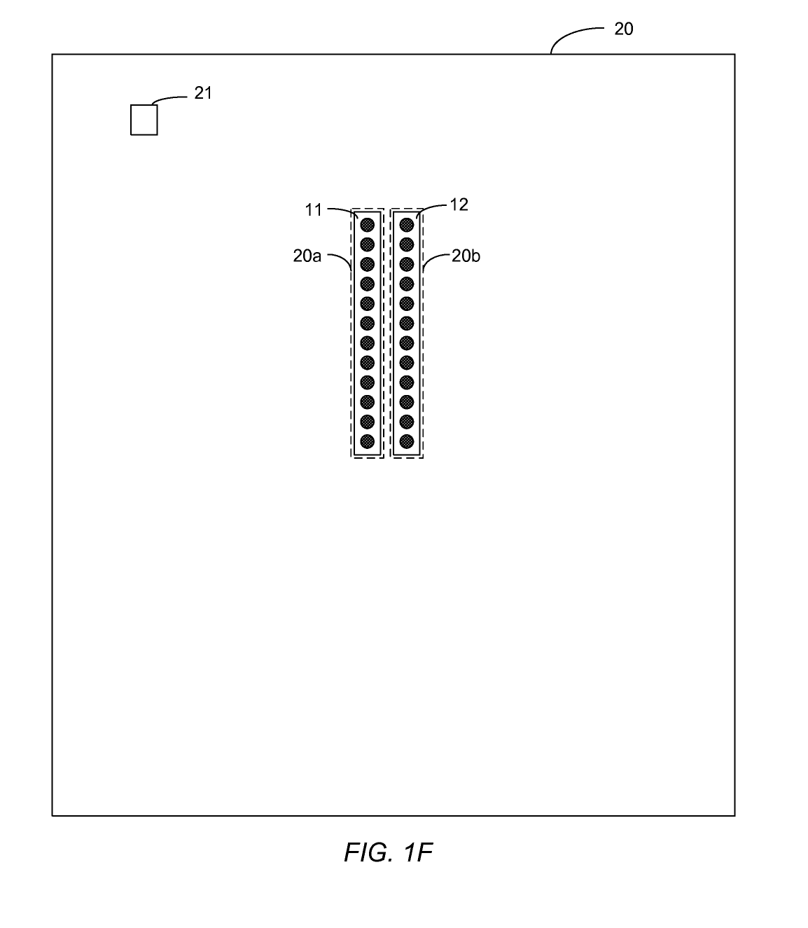

Illustrative, or exemplary, embodiments of the precision die-attach system and method will now be described with reference to FIGS. 1A-4, in which like reference numerals are used to identify like, components, features or elements. It should be noted components, features or elements in the drawings are not drawn to scale. FIG. 1A illustrates a top plan view of first and second precision-alignment receptacles 1 and 2, respectively, prior to array dies being placed therein. FIG. 1B illustrates a top plan view of the first and second precision-alignment receptacles 1 and 2 shown in FIG. 1A after first and second array dies 11 and 12 have been placed therein, respectively, but prior to the array dies 11 and 12 being aligned and oriented in the receptacles 1 and 2. FIG. 1C illustrates a top plan view of the first and second precision-alignment receptacles 1 and 2 shown in FIG. 1B with the first and second array dies 11 and 12 aligned and oriented in the receptacles 1 and 2, respectively. FIG. 1D illustrates a top plan view of the first and second precision-alignment receptacles 1 and 2 shown in FIG. 1C with the first and second array dies 11 and 12 aligned and oriented in the receptacles 1 and 2, respectively, and with the receptacles 1 and 2 being positioned over a mounting surface 20 as the array dies 11 and 12 are mounted on the mounting surface 20. FIG. 1E illustrates a top plan view of the first and second array dies 11 and 12 mounted on the mounting surface 20 in alignment with a fiducial mark 21 disposed on the mounting surface 20.

The first and second precision-alignment receptacles 1 and 2 are components of the die-attach system of the present invention. The die-attach system typically includes a pick-and-place machine (not shown for purposes of clarity) and a machine vision system (not shown for purposes of clarity). The first receptacle 1 includes at least side walls 1a and 1b, a bottom 1c and first and second alignment/orientation mechanisms 1d and 1e, respectively. The first receptacle 1 may also include side walls 1f and 1g and a top (not shown for purposes of clarity). The second receptacle 2 includes at least side walls 2a and 2b, a bottom 2c and third and fourth alignment/orientation mechanisms 2d and 2e, respectively. The second receptacle 2 may also include side walls 2f and 2g and a top (not shown for purposes of clarity).

The alignment/orientation mechanisms 1d, 1e, 2d and 2e and the side walls 1a, 1b, 2a, and 2b are used to align and orient the array dies 11 and 12 relative to the receptacles 1 and 2, respectively, as will now be described. A robotic arm (not shown for purposes of clarity) places the dies 11 and 12 in the general locations shown in FIG. 1B. In other words, the robotic arm places die 11 on bottom 1c at any location that is surrounded by the alignment/orientation mechanisms 1d and 1e and the side walls 1a and 1b. Likewise, the robotic arm places die 12 on bottom 2c at any location that is surrounded by the alignment/orientation mechanisms 2d and 2e and the side walls 2a and 2b. The orientations of the dies 11 and 12 when placed on the bottoms 1c and 2c is not important, except that the dies 11 and 12 are right side up (i.e., light-emitting or light-receiving regions facing up) and sides 11a and 12a of the dies 11 and 12, respectively, are closer to side walls 1a and 2a of the receptacles 1 and 2, respectively, than are any other sides of the dies 11 and 12.

The alignment/orientation mechanisms 1d, 1e, 2d, and 2e are capable of moving in the directions indicated by the respective arrows shown in FIG. 1A. After the dies 11 and 12 have been placed on the bottoms 1c and 2c, respectively, as shown in FIG. 1B, the alignment/orientation mechanisms 1d, 1e, 2d, 2e are moved in the directions indicated by the respective arrows 4-7 shown in FIG. 1C. As the alignment/orientation mechanisms 1d and 1e are moved in the respective directions indicated by arrows 4 and 5 in FIG. 1C, the alignment/orientation mechanisms 1d and 1e come into contact with respective sides of the respective die 11 and push the die 11 into the position and orientation shown in FIG. 1C in which sides 11a and 11b of die 11 are in contact with side walls 1a and 1b, respectively, of the receptacle 1. The side walls 1a and 1b form a first alignment/orientation feature that mates with the sides 11a and 11b of the die 11. Likewise, as the alignment/orientation mechanisms 2d and 2e are moved in the respective directions indicated by arrows 6 and 7 in FIG. 1C, the alignment/orientation mechanisms 2d and 2e come into contact with respective sides of the respective die 12 and push the die 12 into the position and orientation shown in FIG. 1C in which sides 12a and 12b of die 12 are in contact with side walls 2a and 2b, respectively, of the receptacle 2. When the dies 11 and 12 are in the positions and orientations shown in FIG. 1C, the dies 11 and 12 are precisely aligned with the receptacles 1 and 2, respectively. The side walls 2a and 2b form a second alignment/orientation feature that mates with the sides 12a and 12b of the die 12.

In FIG. 1D, the receptacles 1 and 2 with the dies 11 and 12 loaded therein are shown positioned over mounting surface 20 on which the dies 11 and 12 will be mounted. The mounting surface 20 has at least one fiducial mark 21 disposed thereon that will be used by the system to align the receptacles 1 and 2 with the mounting surface 20. For illustrative purposes, the fiducial mark 21 is shown as being disposed on the mounting surface 20, but, as indicated above, it could be disposed at any suitable location that enables it to be used for relative alignment of the receptacles 1 and 2 with particular mounting locations on the mounting surface 20. For illustrative purposes, it will be assumed that the mounting surface 20 is a substrate of a PCB of an ESA, which is typically the case.

When the system determines that the receptacles 1 and 2 are aligned and oriented with the mounting surface 20, this is also a determination that the dies 11 and 12 are aligned and oriented with their respective mounting locations on the mounting surface 20 due to the precise alignment and orientation of the dies 11 and 12 relative to the receptacles 1 and 2, respectively. Thus, when relative alignment and orientation is achieved between the receptacles 1 and 2 and the mounting surface 20, the dies 11 and 12 are ready to be placed on the mounting surface 20. The manner in which one or more fiducial marks can be used by a machine vision system to determine when a device is aligned and oriented relative to a mounting surface is well known, and therefore will not be described herein in the interest of brevity.

When the dies 11 and 12 are ready to be placed on the mounting surface 20, there must be some way of doing this without interfering with the established alignment and orientation of the dies 11 and 12 with the mounting surface 20. Although this can be achieved in a number of ways, in accordance with an illustrative embodiment, the bottoms 1c and 2c of the receptacles 1 and 2, respectively, are made retractable to allow them to be moved in the directions indicated by arrows 23 and 24, respectively, in FIG. 1D. As the bottoms 1c and 2c are retracted in the respective directions indicated by arrows 23 and 24, the alignment/orientation mechanisms 1d, 1e, 2d, 2e remain in their relative positions in which they are in contact with the respective surfaces of the dies 11 and 12 and are pressing the surfaces 1a/2a and 1b/2b of the dies 11 and 12 against the side walls 1a/2a and 1b/2b of the receptacles 1 and 2. This prevents the dies 11 and 12 from moving out of their aligned and oriented positions as the bottoms 1c and 2c of the receptacles 1 and 2 are retracted. Retraction of the bottoms 1c and 2c lowers the dies 11 and 12 onto their respective mounting locations on the mounting surface 20. If needed, ejector pins (not shown) may be included in the receptacles 1 and 2 for exerting forces against the dies 11 and 12 in directions normal to the mounting surface 20 to eject the dies 11 and 12 from the receptacles 1 and 2. Typically, an adhesive material such as epoxy or the like is pre-dispensed on the mounting locations to fixedly secure the dies 11 and 12 to the mounting surface 20.

Once the dies 11 and 12 have been lowered onto the mounting surface 20, the alignment/orientation mechanisms 1d, 1e, 2d, 2e are moved away from the dies 11 and 12 to return them to their respective start positions, as shown in FIG. 1E. The receptacles 1 and 2 are then lifted up in a direction normal to the mounting surface 20 and moved away from the mounting surface 20, leaving the dies 11 and 12 in the respective mounting locations 20a and 20b on the mounting surface 20, as shown in FIG. 1F. The receptacles 1 and 2 may then be returned to the start or home position shown in FIG. 1A so that the process can be repeated with another pair of dies and another mounting surface.

The process described above of loading the dies 11 and 12 into the respective receptacles 1 and 2, aligning and orienting the dies 11 and 12 within the respective receptacles 1 and 2, aligning and orienting the receptacles 1 and 2 with the mounting surface 20, placing the dies 11 and 12 in their respective mounting locations 20a and 20b on the mounting surface 20, and returning the receptacles 1 and 2 to the start or home position shown in FIG. 1A can be entirely automated so that no operator interaction with the system is required. For example, the system can incorporate known technology that automatically loads the dies 11 and 12 into the respective receptacles, imparts movement to the alignment/orientation mechanisms 1d/1e/and 2d/2e to align and orient the dies 11 and 12 with the receptacles 1 and 2, imparts movement to the receptacles 1 and 2 and/or to the mounting surface 20 to align and orient the receptacles 1 and 2 with the mounting surface 20, imparts movement to the bottoms 1c and 2c to retract them to place the dies 11 and 12 in their respective mounting locations 20a and 20b on the mounting surface 20, and imparts movement to the receptacles 1 and 2 to return them to the start or home position. Persons of skill in the art will understand, in view of the description being provided herein, the manner in which such an automated assembly processes and system can be implemented using existing technology.

The dies 11 and 12 are shown as being 1×12 array dies, but the system and process can accommodate any 1×N array dies, where N is an integer that is equal to or greater than one. Also, the alignment/orientation mechanisms of the receptacles 1 and 2 are not limited to having any particular shapes, sizes, configurations or directions of travel. The mechanisms 1d, 1e, 2d, and 2e are merely examples of suitable mechanisms that may be part of an alignment/orientation system that performs this process. As will be understood by those of skill in the art, in view of the description being provided herein, the shapes, sizes, configurations, and directions of travel of the alignment/orientation mechanism(s) of the alignment/orientation system will depend on the shapes and sizes of the dies that are being aligned and oriented and may depend on other factors as well, such as the configuration of the receptacles 1 and 2.

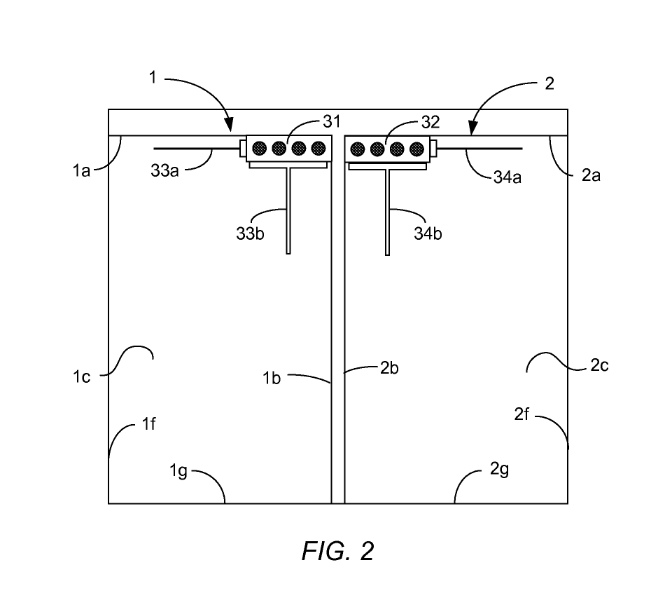

For example, FIG. 2 illustrates a top plan view of the receptacles 1 and 2 in accordance with another illustrative embodiment in which 1×4 array dies 31 and 32 are aligned and oriented by the respective side walls 1a, 1b, 2a and 2b of the receptacles 1 and 2. The alignment/orientation mechanisms 1d, 1e, 2d, and 2e have been modified into alignment/orientation mechanisms 33a, 33b, 34a, 34b, respectively. The alignment/orientation mechanisms 33a, 33b, 34a, and 34b align and orient the dies 31 and 32 with the respective receptacles 1 and 2 in the same manner in which mechanisms 1d, 1e, 2d, and 2e align and orient dies 11 and 12 with the respective receptacles 1 and 2.

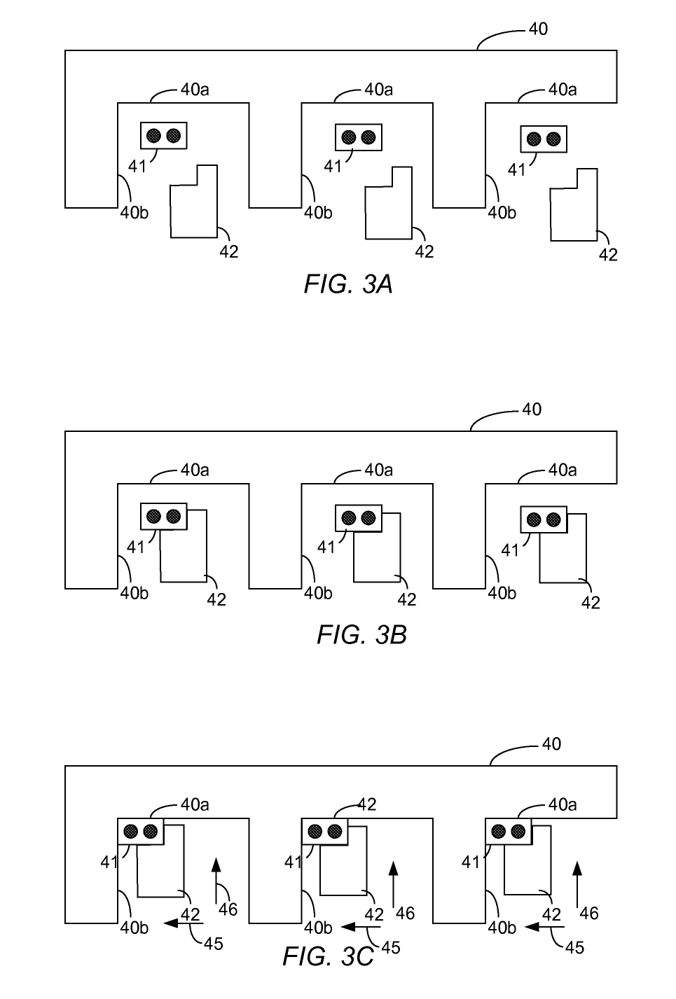

FIGS. 3A-3C illustrate top plan views of a precision-alignment receptacle 40 in accordance with another illustrative embodiment for aligning and orienting dies and for maintaining the alignment and orientation of the dies as they are placed on the mounting surface (not shown). In accordance with this illustrative embodiment, the dies are 1×2 array dies 41, each of which has two optoelectronic elements, such as laser diodes, for example. The precision-alignment receptacle 40 has three sets of side walls 40a and 40b, each of which forms an alignment/orientation feature. In accordance with this illustrative embodiment, alignment/orientation mechanisms 42 have 90° corners formed therein for engaging respective corners of the respective dies 41, as shown in FIG. 3B. The alignment/orientation mechanisms 42 are movable in the directions indicated by arrows 45 and 46 in FIG. 3C.

As the mechanisms 42 move in these directions, they cause the respective dies 41 to be pressed against respective side walls 40a and 40b of the receptacle 40 and eventually into the respective alignment/orientation features formed by the respective side walls 40a and 40b, as shown in FIG. 3C. When the dies 41 are in the positions shown in FIG. 3C, they are aligned and oriented relative to the receptacle 40 and relative to one another. Processes similar or identical to the processes described above with reference to FIGS. 1D and 1E are then used to place the dies 41 in their respective mounting locations on a mounting surface (not shown).

By using the precision-alignment receptacles and process of the invention described above to orient and align the dies relative to the receptacles and relative to one another, and by maintaining the orientation and alignment throughout the placement process, the pick-and-place machine that is used to place the dies on the mounting surface does not have to be so precise and can be made at relatively low cost compared to high-precision pick-and-place machines. The precision-alignment receptacles described above are typically made of metal and are typically formed by a process known as electrical discharge machining (EDM). EDM is a process that allows metal parts to be performed very precisely. Using EDM to form the receptacles ensures that the side walls of the receptacles that are used as alignment features are very precisely formed and ensures that the relative positioning of the side walls of the receptacles is very precise. This, in turn, ensures that once the dies are aligned and oriented within the receptacles, they are aligned and oriented relative to one another, which can be important in parallel transceiver modules that incorporate laser diode and photodiode arrays that need to be aligned with one another and with the mounting surface on which they are mounted.

If the pitch between the elements of the array dies is so small that the necessary precision of the receptacles cannot be achieved using EDM, then an alternative is to etch an interposer with the necessary precision using photolithographic techniques. The interposer can then be used as the precision-alignment receptacle to align and orient the dies on the pick-and-place machine prior to mounting them on the mounting surface. The interposer with the dies thereon is then mounted on the mounting surface by the pick-and-place machine. As with the receptacles described above, the main advantage to using the interposer in this way is that the pick-and-place machine that is used to place the dies on the mounting surface does not have to be so precise and can be made at relatively low cost compared to high-precision pick-and-place machines. Another advantage to using the interposer for this purpose is that the lower surface of the interposer can function as a heat sink device to dissipate heat generated by the array dies.

The interposer can look identical to the receptacles 1 and 2 shown in FIG. 1A, but the side walls 1a/1b and 2a/2b are precisely formed by lithographically etching them using known lithography techniques, or by using some other type of etching technique that is capable of achieving the needed precision. The dies 11 and 12 are then aligned and oriented on the interposer in the same manner described above in which the dies 11 and 12 are aligned and oriented on the receptacles 1 and 2. However, during the process of mounting the dies 11 and 12 on the mounting surface 20, the entire interposer with the dies 11 and 12 mounted thereon is mounted on the mounting surface by the pick-and-place machine.

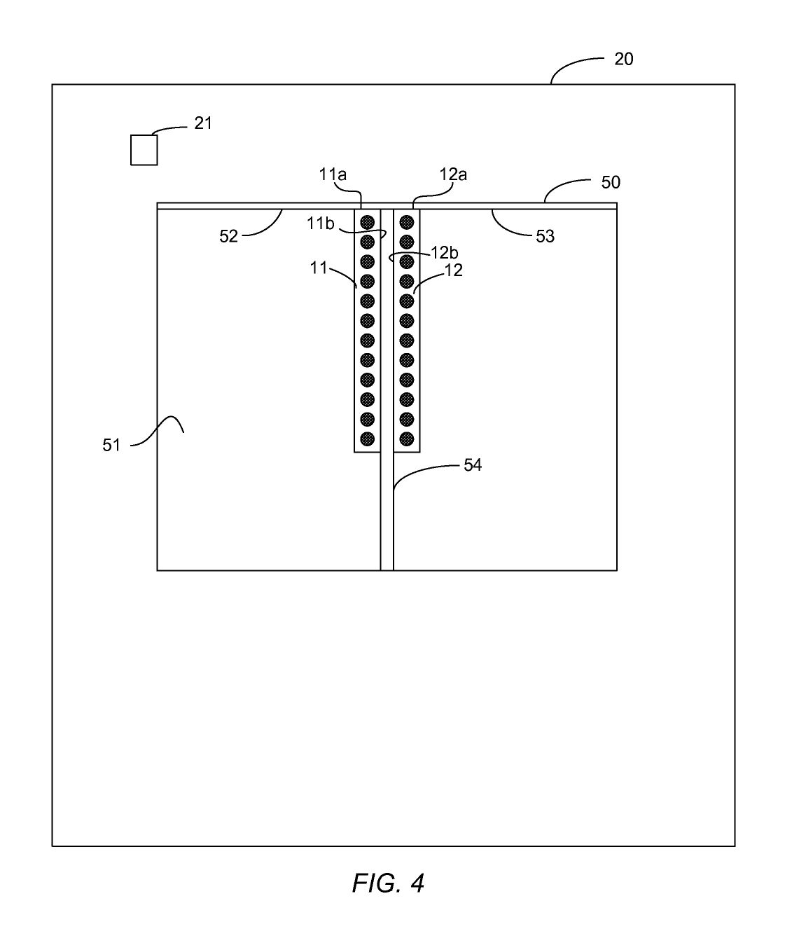

FIG. 4 illustrates a top plan view of the mounting surface 20 with the interposer 50 mounted thereon. The interposer 50 has a top surface 51 that has been etched to form side walls 52, 53 and 54 with very high precision. The interposer 50 is typically made of etched silicon, although it could be made of any material that can be precisely etched. As shown, sides 11a and 11b of the die 11 are in contact with the side walls 52 and 54 of the interposer 50, respectively, thereby ensuring that the die 11 is precisely aligned with the interposer 50. In other words, the side walls 52 and 54 form a first alignment/orientation feature that mates with the sides 11a and 11b of the die 11. Likewise, the side walls 53 and 54 form a second alignment/orientation feature that mates with the sides 12a and 12b of the die 12, thereby ensuring that the die 12 is precisely aligned with the interposer 50. An adhesive material such as epoxy is typically placed on the surface 51 of the interposer 50 prior to aligning and orienting the dies 11 and 12 thereon to fixedly secure the dies 11 and 12 in their aligned and oriented positions on the interposer 50. When the interposer 50 with the dies 11 and 12 fixedly secured thereto is mounted on the mounting surface 20, the interposer 50 is aligned with the fiducial mark 21, which ensures that the dies 11 and 12 are also aligned with the fiducial mark 21 and with one another.

The dies 11, 12, 31, 32, and 42 described above with reference to FIGS. 1B-4 are array dies that have arrays of laser diodes or arrays of photodiodes formed therein. However, the die-attach systems and methods described herein are not limited to such dies, but apply equally to other types of IC dies. The term “IC die,” as that term is used herein, is intended to denote any type of semiconductor die that has one or more circuits integrated therein, including, but not limited to, laser diode array dies and photodiode array dies.

Illustrative embodiments of systems and methods for singulating, or dicing, dies that are suitable for use with the precision die-attach systems and methods described above with reference to FIGS. 1A-4 will now be described with reference to FIGS. 5-13, in which like reference numerals represent like elements, components or features. FIG. 5 illustrates a pictorial diagram of a plasma etching chamber that may be used to perform plasma etching to dice compound semiconductor wafers into dies. Plasma etching techniques have been used to dice compound semiconductor wafers into dies, so any known techniques and tools are suitable for this purpose. The system 100 includes an etching chamber 102, a cooling system 103, a first radio frequency (RF) power source 104, and a second RF power source 105. In accordance with this illustrative embodiment, the first RF power source 104 is a 13.56 megahertz (MHz) RF power source and the second RF power source 105 is a 2 MHz RF power source. The first RF power source 104 is used for setting the bias voltage of the semiconductor wafer 106, which is positioned on an adhesive-bearing side of a piece of tape 107. The piece of tape 107 is positioned on an upper surface of a plate 108 that is electrically coupled to the first RF power source 104. The second RF power source 105 is used for setting the bias voltage of an upper plate 109, which is electrically coupled to the second RF power source 105.

The first and second RF power sources 104 and 105 provide time-varying electrical currents that create time-varying magnetic fields about a rarefied gas (not shown) disposed in the chamber 102. The time-varying magnetic fields induce electrical currents in the gas to create a plasma 110. This process of creating plasma is referred to in the art as an inductively coupled plasma (ICP) process. The gas chemistry that is used in the chamber 102 is typically based on either a methane base (CH₄) or a chlorine base (Cl₂, BCl₃). Different gas ratios are used to etch different types of compounds, and therefore the gas ratio that is used to etch the wafer 106 will depend on the compound comprising the wafer 106. The wafer compound is typically a III-V compound (i.e., made up of combination of two or more of Ga, As, Al, In, and Ph).

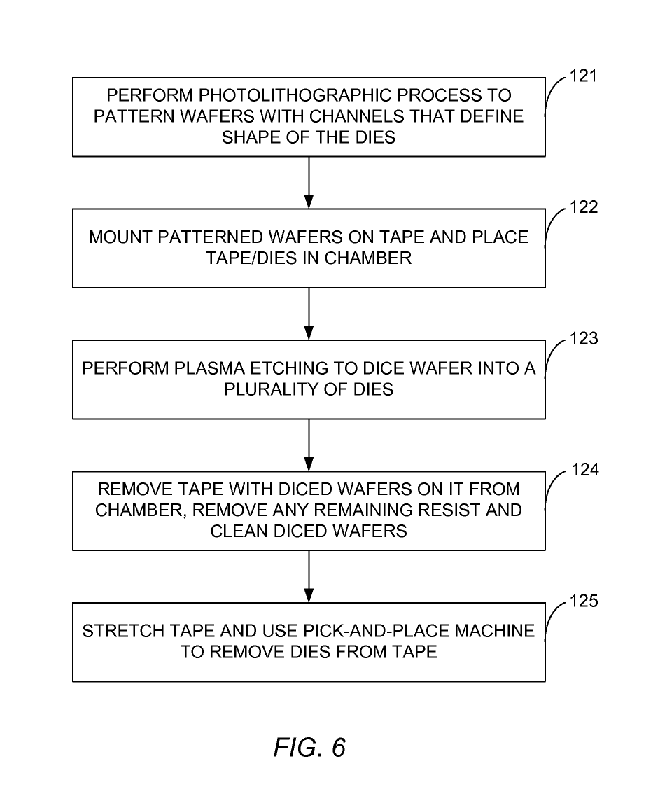

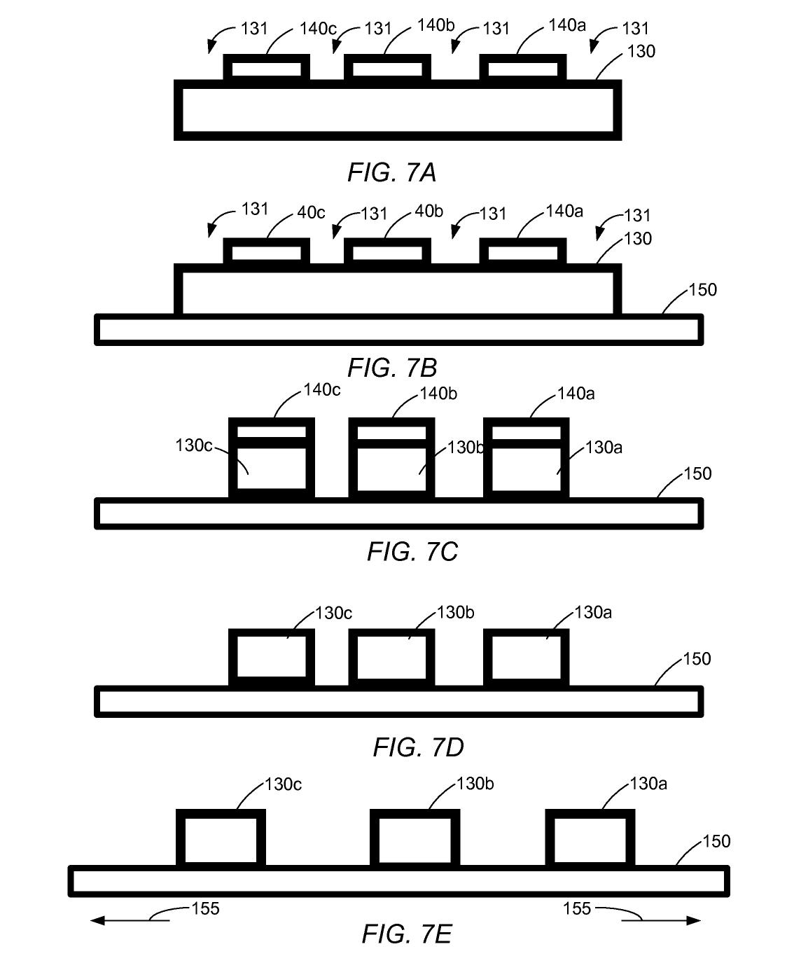

FIG. 6 is a flowchart that represents the method performed by the system shown in FIG. 5. FIGS. 7A-7E are side plan views of a compound semiconductor wafer 130 as it is processed in accordance with the method represented by the flowchart shown in FIG. 6. The method will be described with reference to FIGS. 6 and 7A-7E. Known photolithographic processing steps are performed to form openings, or channels, 131 (FIGS. 7A and 7B) in a layer of photoresist 140 disposed on an upper surface of the wafer 130, leaving a patterned photoresist layer 140a, 140b and 140c on top of the upper surface of the wafer 130. This step is represented by block 121 in FIG. 6 and the device shown in FIG. 7A. The patterned photoresist layer 140a-140c acts as a mask that will protect the covered portions of the wafer 130 from the subsequent plasma etching process while leaving the uncovered, exposed portions of the wafer 130 vulnerable to the subsequent plasma etching process. While photolithographic processes are well suited for creating the mask, any suitable process and material may be used to create the mask.

The wafer 130 having the patterned photoresist layer 140a-140c on it is then placed on an adhesive-bearing side of a piece of tape 150, as indicated by block 122 in FIG. 6 and FIG. 7B. The tape 150 having the wafer 130 on it, as shown in FIG. 7B, is then placed inside of the chamber 102 shown in FIG. 5 and subjected to the plasma etching process described above with reference to FIG. 5. This step is represented by block 123 in FIG. 6 and by FIG. 7C. It can be seen in FIG. 7C that the portions of the wafer 130 that are not masked from the plasma etch by the patterned photoresist layer 140a-140c are etched away, leaving only the masked portions of the wafer 130 and the photoresist 140a-140c disposed on top of it. The masked portions of the wafer 130 correspond to the individual dies 130a, 130b and 130c.

After the plasma etching process has been completed, the tape 150 having the wafer 130 thereon is removed from the chamber 102 and the remaining photoresist layer 140a-140c is removed using ashing and chemical rinse processes (not shown for purposes of clarity), leaving only the tape having the dies 130a, 130b and 130c thereon. This step is represented by block 124 in FIG. 6 and by FIG. 7D. The tape 150 is then stretched in the directions indicated by arrows 155 in FIG. 7E and by block 125 in FIG. 6 to increase the lateral spacing between the dies 130a-130c. Stretching the tape 150 in this manner makes it easier for a pick-and-place machine (not shown for purposes of clarity) to be used to pick the dies 130a-130c up off of the tape 150.

Using the plasma etching process described above to dice the wafer 130 allows the dies to have any shape that can be defined by patterning photoresist, unlike conventional techniques used for dicing compound semiconductor wafers, which only allow dies having fixed rectangular shapes to be formed. In addition, using the plasma etching process results in the dies having very smooth side walls, which is generally not the case with conventional sawing or cutting singulation processes used for dicing compound semiconductor wafers. With the plasma etch dicing process, smoothness of the side walls is such that side wall variations from die to die are typically less than 10 microns, and often less than 5 microns. Such dies are well suited for use with the precision-alignment receptacles described above with reference to FIGS. 1A-4.

Furthermore, using the plasma etching process allows the dies to have any desired side wall profile. The plasma etching process such as described above with reference to FIGS. 5-7E may be used to dice wafers into dies that have non-rectangular shapes. FIGS. 8-13 illustrate top plan views of compound semiconductor dies having a variety of non-rectangular shapes that have been made using the plasma etching method and system described above with reference to FIGS. 5-7E. The die shapes shown in FIGS. 8-12 are a torus 210, a cross 220, a pentagon 230, a triangle 240, and a parallelogram 250, respectively. The die shape 260 shown in FIG. 13 is an irregular, non-rectangular shape having a variety of angles, side wall dimensions and side wall profiles. With conventional sawing or cutting dicing processes often used for dicing compound semiconductor wafers, the indexing of the sawing or cutting tool is fixed, so the die size and the channel width (i.e., the distance between dies) is fixed. Also, with conventional sawing or cutting dicing processes, the sawing or cutting tool is limited to making cuts that are orthogonal to one another such that the dies always are rectangular in shape. With the plasma etch dicing process, a variety of nonrectangular die shapes are obtainable, such as those shown in FIGS. 8-13, for example.

Essentially, any pattern that can be photolithographically formed in the photoresist layer can be transferred onto the wafer to define the shape of the dies. One of the advantages of being able to dice compound semiconductor wafers into dies having non-rectangular shapes is that it allows the shape of the resulting die to be used as a passive alignment feature for precisely aligning the die with an external device or element. Being able to use the shape of the die as a passive alignment feature allows a feature located on one of the surfaces of the die to be brought into alignment with an external device or element by passively aligning one or more walls of the die with an external device or feature having a shape that is complementary to the shape of the die wall or walls that are being used as the passive alignment feature. For example, this passive alignment method could be used to bring a light-emitting facet of a laser diode die into optical alignment with a lens or an end of an optical fiber. As another example, this passive alignment method could be used to bring a light-receiving facet of a photodiode die into optical alignment with a lens or an end of an optical fiber. Thus, while the precision-alignment receptacles have been described above with reference to FIGS. 1A-4 as having straight side walls for aligning and orienting dies that have straight side walls, the precision-alignment receptacles can be manufactured to have any shapes that the dies will have so that the walls of the receptacles mate with the walls of the dies to align and orient the dies with the receptacles.

It should be noted that the systems and methods have been described with reference to a few illustrative embodiments for the purposes of demonstrating the principles and concepts of the invention and to provide a few examples of the manner in which they may be implemented. For example, while the bottoms of the receptacles have been described as being retractable to allow the dies to be unloaded from the receptacles, the process of unloading the dies from the receptacles can be accomplished in a number of ways. For example, instead of the entire bottoms being retractable, only the portions of the bottoms on which the dies sit in the receptacle may be retractable to accomplish the same task of unloading the dies. Also, instead of the dies being oriented right side up on the bottoms of the receptacles, the dies could be placed on the bottoms of the receptacles upside down and then unloaded from the receptacles by flipping the receptacles over when the receptacles are in alignment with the mounting surface. Also, instead of placing the dies on the bottoms of the receptacles, the receptacles could be equipped with respective clips that hold the edges of the dies and that are unclipped to unload the dies from the receptacles. As will be understood by persons skilled in the art in view of the description provided herein, these and a variety of other modifications may be made to the system and method described herein within the scope of the invention.

What is claimed is:

1. A precision die-attach system for aligning and orienting dies to be mounted on a mounting surface, the system comprising:
a first precision-alignment receptacle having a bottom and at least first and second precision-formed side walls, wherein the first and second precision-formed side walls that form a first alignment/orientation feature in the first receptacle, the first alignment/orientation feature having a precise shape and size for mating with first and second side walls of a first integrated circuit (IC) die; and
a second precision-alignment receptacle having a bottom and at least third and fourth precision-formed side walls, wherein the third and fourth precision-formed side walls form a second alignment/orientation feature in the second receptacle, the second alignment/orientation features having a precise shape and size for mating with first and second side walls of a second IC die, and wherein mating of the first and second IC dies with the first and second alignment/orientation features of the first and second receptacles, respectively, precisely aligns and orients the first and second IC dies with the first and second receptacles, respectively, and with one another, and wherein the precision die-attach system is configured to place the first and second IC dies onto a mounting surface while maintaining the precise alignment and orientation of the first and second IC dies with one another.

2. The precision die-attach system of claim 1, wherein the first and third side walls are parallel to one another and a first end of the third side wall is adjacent a second end of the first side wall.

3. The precision die-attach system of claim 2, wherein the first and second side walls are perpendicular to one another.

4. The precision die-attach system of claim 3, wherein the third and fourth side walls are perpendicular to one another.

5. The precision die-attach system of claim 1, wherein the first and second side walls are non-perpendicular to one another.

6. The precision die-attach system of claim 5, wherein the third and fourth side walls are non-perpendicular to one another.

7. The precision die-attach system of claim 1, further comprising an alignment/orientation system movably coupled to the first and second receptacles for imparting motion to the first and second IC dies, respectively, to cause the first and second sides of the first and second dies to be mated with the first and second alignment/orientation features, respectively, of the first and second receptacles, respectively.

8. The precision die-attach system of claim 7, wherein the bottoms of the first and second receptacles are retractable to allow the first and second IC dies to be unloaded from the first and second receptacles, respectively, and placed on the mounting surface.

9. The precision die-attach system of claim 8, wherein the alignment/orientation system is operable to press the first and second IC dies into mating engagement with the first and second alignment/orientation features, respectively, of the first and second receptacles, respectively, as the bottoms of the first and second receptacles are retracted.

10. The precision die-attach system of claim 1, wherein the first and second receptacles are integrally formed in a unitary machined metal part.

11. A precision die-attach system for aligning and orienting dies to be mounted on a mounting surface, the system comprising:
a precision-etched interposer, the precision-etched interposer comprising:
an etched first precision-alignment receptacle having a bottom and at least first and second precision-etched side walls, wherein the first and second precision-etched side walls form a first alignment/orientation feature in the first receptacle, the first alignment/orientation feature having a precise shape and size for mating with first and second sides of a first integrated circuit (IC) die; and
an etched second precision-alignment receptacle having a bottom and at least third and fourth precision-etched side walls, wherein the third and fourth precision-etched side walls form a second alignment/orientation feature in the second receptacle, the second alignment/orientation feature having a precise shape and size for mating with first and second side walls of a second IC die, wherein the first and second receptacles are integrally formed in an etched material, and wherein mating of the first and second sides of the first and second IC dies with the first and second alignment/orientation features of the first and second receptacles, respectively, precisely aligns and orients the first and second IC dies with the first and second receptacles, respectively, and with one another, and wherein the precision die-attach system is configured to place the interposer having the first and second IC dies aligned and oriented with the first and second receptacles, respectively, onto a mounting surface while maintaining the precise alignment and orientation of the first and second IC dies with the first and second receptacles, respectively.

12. The precision die-attach system of claim 11, wherein the first and third side walls are parallel to one another.

13. The precision die-attach system of claim 12, wherein the first and second side walls are perpendicular to one another.

14. The precision die-attach system of claim 13, wherein the third and fourth side walls are perpendicular to one another.

15. The precision die-attach system of claim 11, wherein the first and second side walls are non-perpendicular to one another.

16. The precision die-attach system of claim 15, wherein the third and fourth side walls are non-perpendicular to one another.

17. The precision die-attach system of claim 11, further comprising an alignment/orientation system movably coupled to the first and second receptacles for imparting motion to the first and second IC dies, respectively, to cause the first and second side walls of the first and second dies to be mated with the first and second alignment/orientation features, respectively, of the first and second receptacles, respectively.

18. The precision die-attach system of claim 11, wherein the first and second receptacles are made of an etched material.

19. A method for performing precision die attachment of integrated circuit (IC) dies on a mounting surface, the method comprising:
providing a first precision-alignment receptacle having a bottom and at least first and second precision-formed side walls, wherein the first and second precision-formed side walls form a first alignment/orientation feature in the first receptacle, the first alignment/orientation feature having a precise shape and size for mating with first and second side walls of a first IC die;
providing a second precision-alignment receptacle having a bottom and at least third and fourth precision-formed side walls, wherein the third and fourth precision-formed side walls form a second alignment/orientation feature in the second receptacle, the second alignment/orientation feature having a precise shape and size for mating with first and second side walls of a second IC die, wherein the first and second receptacles are integrally formed in an etched material;
aligning and orienting the first and second side walls of the first and second IC dies with the first and second alignment/orientation features of the first and second receptacles, respectively, wherein aligning and orienting the first and second side walls of the first and second dies with the first and second alignment/orientation features, respectively, precisely aligns and orients the first and second IC dies with the first and second receptacles, respectively, and with one another; and
placing the first and second IC dies onto a mounting surface while maintaining the precise alignment and orientation of the first and second IC dies with one another.

20. The method of claim 19, wherein the step of aligning and orienting the first and second IC dies with the first and second alignment/orientation features of the first and second receptacles, respectively, further comprising:
using an alignment/orientation system movably coupled to the first and second receptacles to impart motion to the first and second IC dies, respectively, to cause the first and second sides of the first and second dies to be mated with the first and second alignment/orientation features, respectively, of the first and second receptacles, respectively.

21. The method of claim 20, wherein the step of placing the first and second IC dies onto the mounting surface includes retracting the bottoms of the first and second receptacles to allow the first and second IC dies to be unloaded from the first and second receptacles, respectively, and placed on the mounting surface.

22. The method of claim 21, wherein the step of placing the first and second IC dies onto the mounting surface includes aligning and orienting the first and second receptacles with one or more fiduciary marks, and wherein the step of aligning and orienting the first and second receptacles with said one or more fiduciary marks results in alignment and orientation of the first and second dies with first and second mounting locations, respectively, of the mounting surface, and wherein the first and second dies are placed in the first and second mounting positions on the mounting surface.

23. A method for performing precision die attachment of integrated circuit (IC) dies on a mounting surface, the method comprising:
providing a precision-etched interposer, the precision-etched interposer having first and second precision-alignment receptacles formed therein, the first precision-alignment receptacle having a bottom and at least first and second precision-etched side walls, wherein the first and second precision-etched side walls intersect to form a first corner in the receptacle, the first corner having a precise shape and size for mating with a precisely shaped and sized corner of a first IC die, the second precision-etched receptacle having a bottom and at least third and fourth precision-etched side walls, wherein the third and fourth precision-etched side walls intersect to form a second corner in the second receptacle, the second corner having a precise shape and size for mating with a precisely shaped and sized corner of a second IC die;
aligning and orienting the first and second IC dies with the first and second corners of the first and second receptacles, respectively, and fixedly securing the first and second IC dies in the respective aligned and oriented positions, wherein aligning and orienting the first and second dies with the first and second corners, respectively, precisely aligns and orients the first and second IC dies with the first and second receptacles, respectively, and with one another; and
aligning and orienting the interposer with a mounting surface and placing the interposer on the mounting surface while maintaining the alignment and orientation of the interposer with the mounting surface.

24. The method of claim 23, wherein the step of aligning and orienting the first and second IC dies with the first and second corners of the first and second receptacles, respectively, further comprising:
using an alignment/orientation system movably coupled to the first and second receptacles to impart motion to the first and second IC dies, respectively, to cause the corners of the first and second dies to be mated with the first and second corners, respectively, of the first and second receptacles, respectively.

25. The method of claim 24, wherein the step of aligning and orienting the interposer with the mounting surface includes aligning and orienting the interposer with one or more fiduciary marks, and wherein the step of aligning and orienting the interposer with said one or more fiduciary marks results in alignment and orientation of the first and second dies with the mounting surface.
